(19) United States
(12) Patent Application Publication
(10) Pub. No.: US 2008/0072960 A1
(43) Pub. Date: Mar. 27, 2008

(54) Phthalocyanine compound for solar cells

(76) Inventors: Mi-Ra Kim, Pusan (KR); Ki Suck Jung, Busan (KR); Sang-Min Han, Pusan (KR); Dong-Yoon Kim, Ulsan (KR); Hyun Seok Jeong, Busan (KR); Il-Jo Choi, Pusan (KR); Eun-Ha Jeong, Yangsan (KR)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/526,618

(22) Filed: Sep. 26, 2006

(51) Int. Cl. H01L 31/00

(52) U.S. Cl. 136/263

(57) ABSTRACT

The present invention provides an electrolyte for solar cells, comprising a phthalocyanine (Pc) compound of Formula I as described herein, and solar cells using the same. According to the invention, energy conversion efficiency of the solar cells was improved by employing the phthalocyanine compound to the solar cells.

### FIELD OF THE INVENTION

The present invention provides an electrolyte for solar cells, comprising at least one phthalocyanine (Pc) compound of Formula I as described herein, and solar cells using the same. According to the invention, energy conversion efficiency of the solar cells was improved by employing the phthalocyanine compound to the solar cells.

### BACKGROUND OF THE INVENTION

Photovoltaic or solar cells are defined as a device which produces electricity by directly converting solar light into electricity through photovoltaic effect. Solar cells already being widely used in our lives, are employed as a power source for clocks, calculators, and further as an electric energy source of aeronautics such as satellite communication. Recently, such non-pollution induced alternative energy source has become more important due to increasing cost of crude oil, depletion of fossil fuels, regulation over emission of carbon dioxides, etc.

Solar cells are classified according to their component materials to several categories such as a solar cell consisting of inorganic materials (e.g. silicon, composite semiconductor, etc.), a dye sensitized solar cell (DSSC) wherein the dye is adsorbed onto nanocrystalline oxide particles, and a solar cell comprising organic molecules having a donor-acceptor structure. Further, according to the cell structure, solar cells can be classified to pn-junction and photoelectrochemical types. DSSC is an example of photoelectrochemical-type, while a solar cell comprising organic molecules is an example of pn-junction type solar cells.

### BRIEF DESCRIPTION OF THE DRAWINGS

FIG. 1 shows the structure of the Dye-Sensitized Solar Cells (DSSCs) device;

FIG. 2 shows FT-IR absorption spectra of oxytitanyl phthalocyanines(TiOPcs) in the wavenumber range of 650-850 cm⁻¹ super; (a) PcT2000R: alpha-form; (b) PcT3000R: beta-form; (c) PcT100S: gamma-form.

FIG. 3 shows the X-ray diffraction (XRD) patterns and the Transmission electron microscope (TEM) images of the TiOPcs; (a) PcT2000R: alpha-form; (b) PcT3000R: beta-form; (c) PcT100S: gamma-form.

FIG. 4 shows the photocurrent-voltage characteristics of the DSSC devices prepared in Example 1 (a) in the dark (b) under AM 1.5; light density: 100 mA/cm2; active area: 0.25 cm2;

FIG. 5 illustrates the mechanisms of electron transfer in the contact interface (a) without a co-adsorbent; (b) with a co-adsorbent; (S=Sensitizer, C=Co-adsorbent.)

FIG. 6 shows the SEM surface images of the working electrode; (a) nanocrystalline porous TiO₂ film; (b) the dyes-adsorbed TiO₂ film; (c) polymer electrolyte film containing polyethyleneglycol (PEG) and PcT3000R; (d) the magnified image of (c).

FIG. 7 shows the photocurrent_voltage characteristics of the DSSC devices having several polymer matrixs (without TiOPc as a coadsorbent).

FIG. 8 shows the photocurrent_voltage characteristics of the DSSC devices having several polymer matrixs using TiOPc as a coadsorbent.

FIG. 9 shows the chemical structures of various phthalocyanines (Pcs) used.

FIG. 10 shows the photocurrent_voltage characteristics of the DSSC devices having several phthalocyanine compounds as a coadsorbent using a PEG electrolyte.

FIG. 11 illustrates the mechanisms of the electrons delocalization in the contact interface. (a) DSSC device using TiOPc with polymer electrolyte. (b) DSSC device using metal_free phthalocyanine as a co-adsorbent with polymer electrolyte.

FIG. 12 shows the photocurrent_voltage characteristics of the DSSC devices having a phthalocyanine compound as a photosensitizer.

### DETAILED DESCRIPTION OF THE PRESENT INVENTION

### A Dye Sensitized Solar Cell (DSSC)

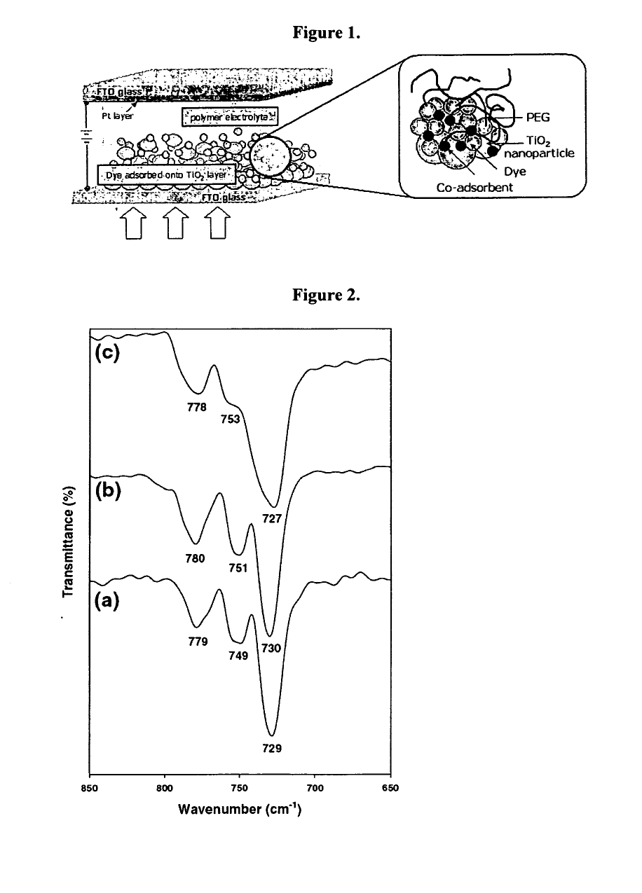

Dye-sensitized solar cell (DSSC), developed by Gratzel et al., using dye molecules which are adsorbed on nanocrystalline metal oxides have attractive features of high power conversion efficiency and low production cost and energy, and easy processing ([M. Gratzel, Nature 421, 586(2003)]). FIG. 1 illustrates cell structures of the DSSC devices. In the DSSC devices, dye molecules produce electron-hole pair and electron is injected into conduction band of semiconductor oxides when solar light (visible light) is absorbed by n-type semiconductor oxide electrodes on which dye molecules are chemically adsorbed. The electron injected to the semiconductor oxide electrode is then transferred to a transparent conducting layer through interface between oxide particles, which produce current. Holes produced by dye molecules are reduced again when receiving electrons from the oxidization-reduction electrolytes to complete the operation of DSSC. However, presence of conventional liquid electrolyte in such cells sometimes leads to problems such as lack of long-term stability, need for sealing, etc. To resolve such problems, many studies for improving the properties of a nanoporous semiconductor oxide layer, chemical and optical properties of a dye as well as the electrolyte have been carried out. Among those, using a quasi-solid state electrolyte is a way to obtain relatively high power conversion efficiency as well as to minimize the power loss [H. Kusama and H. Arakawa, J. Photochem. Photobiol. A: Chem. 164, 103(2004)]).

### A. Semiconductor Oxide (Electrodes)

When selecting appropriate nano-semiconductor oxides for DSSC, energy level of conducting band should be considered first. The energy of conduction band of semiconductors should be lower than LUMO of dyes. The most widely used oxide is TiO₂, of which energy level of conduction energy is about 0.2 eV lower than LUMO energy level of ruthenium-based dye (commercially available under trademarks of the N3 and N719).

### B. Dyes (Photosensitizer)

As a dye for DSSC, ruthenium-based organometallic compounds, organic compounds and quantum-dot inorganic compounds such as InP, CdSe have been known. Until now, ruthenium-based organometallic compounds have been reported as the best dyes for solar cells. Among the ruthenium-based dyes, a representative example is a red-colored N3 which has four hydrogen, and a black-colored N749 dye where two of the four hydrogens of the N3 dye are substituted with tetrabutylammonium ion.

H. Arakawa et al., prepared derivatives of coumarin-based material and utilized them as dyes for DSSC. It showed about 5.2% of power conversion efficiency but unstablility toward light and heat [H. Arakawa et al, J. Phys. chem. B., 107, 597(2003)]. In this regard, there has been no improved dye reported having superior efficiency and stability compared to N3 dyes.

### C. Electrolytes

Electrolytes for DSSC comprises oxidation-reduction species such as I⁻/I₃⁻. LiI, NaI, alkyl ammonium iodide or imidazolium iodide, etc is used as a source of I⁻ super ion, and I₃⁻ ion is prepared by solvating I₂ in solvents. As a medium for electrolytes, a liquid such as acetonitrile or a polymer such as PVdF can be used. I⁻ provides electron to dye molecules and the oxidized I₃⁻ is reduced to I⁻ by receiving electron which is transferred to counter electrode. In the liquid type, a high energy conversion efficiency may be possible since the oxidization-reduction ionic species can move rapidly in the medium which makes reproduction of dyes faster, while liquid leaking may occur when the binding between electrodes are not perfect. In contrast, if polymers are utilized as mediums, liquid leaking rarely occurs but energy conversion efficiency is deteriorated due to slower movement of the oxidization-reduction species. Thus, it is necessary to design electrolytes so that the oxidization-reduction ionic species can move and be transferred in the medium rapidly. Preferable materials for electrolyte include polyacrylonitrile (PAN)-based, poly(vinylidene fluoride-co-hexafluoropropylene (PVdF)-based, combination of acryl-ionic liquid, pyridine-based, and poly(ethyleneoxide) (PEO).

### Organic Solar Cells

Organic solar cells which have been studied since 1990s' are characterized in comprising organic compounds having electron donor (D) and acceptor (A) properties. In organic D-A junction solar cells, electron acceptor corresponds to n-type material of inorganic semiconductor while electron donor corresponds p-type materials. Although they do not have band structures of solid materials, photovoltaic effect due to electron-hole pair formation and transition processes is similar to that of inorganic semiconductor junction solar cells.

Polymeric solar cells which have been researched recently, include conducting polymer (D)/fullerene(A) based, conducting polymer (D)/conducting polymer (A) based and organic polymer (D)/nano inorganics (A) based systems. Recently, S. E. Shaheen, et al., reported 2.5% of energy conversion efficiency at AM 1.5 condition (100 mW/cm²), by using poly[2-methyl-5-(3,7-dimethyl-octyloxy)]-p-phenylenevinylene(MDMO-PPV) as an electron donor[S. E. Shaheen, et al, Appl. Phys. Lett., 78, 841(2001)]. But the energy conversion efficiency is still low.

### Phthalocyanine Materials

Phthalocyanines (Pcs) have attracted the attention of many researchers during the twentieth century and are still being actively studied to this day. Pcs are of enormous technological importance for the manufacture of blue and green pigments and as catalysts for removal of sulfur from crude oil. Other areas of interest include a variety of high technology fields such as for use in semiconductor devices, photovoltaic and other types of solar cell, electrophotography, electronics, electrochromic display devices, photosensitizers and deodorants. Several research results concerning DSSCs which employ the phthalocyanine compound, have been reported recently. However, the power conversion efficiency of those DSSCs were significantly lower than conventional ruthenium bipyridine complex based dye [H. Usui, et al., J. Photochem. Photobiol. A 164, 97 (2004)].

### [Purpose of the Invention]

As described above, demands of materials for a dye, an electrolyte for solar cells in order to show high power conversion efficiency and stability are increasing, and thus many researchers are trying to develop such materials extensively.

As a result of careful consideration with regard to above points, the inventor found that applying a metal-phthalocyanine compound to solar cells unexpectedly improves the performance of solar cells.

### [Technical Constitution]

One aspect of the present invention includes an electrolyte comprising a phthalocyanine compound of Formula I.

X-MPc-(R)ₙ <Formula I>

wherein,
Pc is a phthalocyanine moiety,
M is a metal selected from the group consisting of copper, iron, nickel, cobalt, manganese, aluminum, palladium, tin, indium, lead, titanium, rubidium, vanadium, gallium, terbium, cerium, lanthanum and zinc;
X is none, halogen, —OH or ═O; and
R is independently selected from hydrogen, alkyl, cyclic alkyl, arylalkyl, hydroxyalkyl, amino, alkylamino, alkoxy, alkylthio, aryl, aryloxy, arylthio, halogen and hydroxy groups;
n is an integer from 1 to 16.

In a preferred embodiment, M is selected from the group consisting of titanium, gallium, indium and copper, and most preferably phthalocyanine compound is oxytitanium phthalocyanine.

In another aspect of the present invention, the phthalocyanine compound has a crystal structure selected from gamma, alpha and beta forms, and the crystal structure of beta form is the most preferable.

The electrolyte may further comprise a polymer matrix. The polymer matrix, for example, although not limited to, is selected from the group consisting of polyethylene glycol (PEG), polypropylene glycol (PPG), polyacrylonitriles (PAN), polyacrylates, polymethacrylates (PMMA) and polythiophenes (PT). Among the above polymer matrixes, polyethylene glycol is the most preferable.

Another embodiment of the present invention includes a dye-sensitized solar cell device (DSSC) comprising: a negative electrode, a nanocrystalline metal oxide containing a dye sensitizer; an electrolyte comprising a phthalocyanine compound; and a counter electrode. In various aspects of the DSSC, the dye sensitizer may comprise a ruthenium-bipyridine complex and the nanocrystalline metal oxide comprises a nanocrystalline TiO₂. In another aspect of the DSSC, the negative electrode includes a fluorine-doped tin oxide (FTO) glass and the counter electrode includes FTO glass with thermally deposited Pt. Preferably, the dye sensitizer is adsorbed and covalently bound on the nanocrystalline metal oxide.

In another aspect of the present invention, a dye for a solar cell comprising a phthalocyanine compound of Formula I, and a solar cell comprising the dye, are disclosed. Preferably, the solar cell of the present invention, further comprises: a negative electrode, a nanocrystalline metal oxide, an electrolyte, and a counter electrode, wherein the nanocrystalline metal oxide contains said dye as a dye sensitizer. In another aspect, the solar cell has a structure of electron donor/electron acceptor, wherein the electron donor comprises said dye.

In another aspect of the invention, the use of a phthalocyanine compound of formula I in solar cells is disclosed. Preferably, the phthalocyanine compound of formula I is used as a dye in solar cells and/or as an electrolyte component of the solar cell. When used as an electrolyte component of the solar cell, the phthalocyanine of formula I is preferably used as a coadsorbent.

In a specific embodiment of the invention, a quasi-solid state DSSC is disclosed. The quasi-solid state DSSC is prepared using ruthenium (II) complex dye (N3 dye), a phthalocyanine compound as a co-adsorbent, TiO₂, a counter electrode with deposited Pt. Among phthalocyanine compounds, oxytitanyl phthalocyanine (TiOPc) is preferable since it has a high stability and good optical property.

The present invention is explained in detail below with specific examples. However, the spirit and scope of the invention which is to be determined only by the appended claims, should not be construed to be limited by such embodiments and examples.

### EXAMPLES

### Preparation of DSSC

### Example 1

A DSSC device was established, as described in FIG. 1. The functional components were sandwiched between two FTO(fluorine_doped tin oxide) electrodes. A nanoporous TiO₂ film was deposited of the negative electrode. A dye sensitizer was adsorbed and covalently bound of TiO₂ nanoparticles. The counter electrode consists of FTO with thermally deposited Pt.

The working electrode was prepared as follows. The TiO₂ paste having particle size of 9 nm (Ti-Nanoxide HT/SP, Solaronix Co) was placed on an FTO glass by doctor blade method followed by sintering at 120° C. for about 40 min and at 450° C. for about 60 min in air to give a TiO₂ electrode with an effective area of 0.25 cm², and a TiO₂ film thickness of 10 μm. The nanoporous TiO₂ electrode was dipped in the dye solution that the dye was dissolved in a concentration of 10 mg of cis-bis(isothiocyanato) bis(2,2′-bipyridyl-4,4′-dicarboxylato)-ruthenium (II) bis-tetrabutylammonium dye (N719 dye, Solaronix Co) per 50 ml of absolute ethanol solution at room temperature over night. The dye-adsorbed TiO₂ electrode was dipped in electrolyte solution at room temperature for 24 hours. Polymer electrolyte are contained of 12, tetrabutylammonium iodide (TBAI), 1-ethyl-3-methyl imidazolium iodide (EMImI) as an ionic liquid, ethylene carbonate (EC)/propylene carbonate (PC) (EC:PC=4:1 v/v), polymer matrix such as PEG (Mw=20,000, Aldrich Co), and TiOPc as co-adsorbent in acetonitrile. TiOPcs were prepared by the traditional methods[J. Yao et al., Bull. Chem. Soc. Jpn. 68, 1001 (1995); F. H. Moser, A. L. Thomas, “The Phthalocyanines” vol. 2, CRC press, Boca Raton, Fla., 1983] TiOPcs were named by PcT1100S (gamma-form), PcT2000R (alpha-form), and PcT3000R (beta-form) as their crystal structures. After that, the electrolyte was casted onto dye-adsorbed TiO₂ electrode and was dried at about 60° C. for 2 hours. The counter electrode was also prepared by the similar method that TiO₂ film was coated. Pt paste (Pt catalyst T/SP, Solaronix Co.) was placed on an FTO glass by doctor blade method, followed by sintering at 100° C. for about 10 min prior firing at 450° C. for about 50 min in air.

In assembling of DSSC devices, the working electrode and the counter electrode were clamped together and the intervening space between two electrodes was filled the polymer electrolyte. The cross section and inner structure of DSSC device fabricated is also shown in FIG. 1. The crystal structures of Pcs were confirmed using X-ray Diffraction (XRD), Fourier transfer IR (FT-IR) spectroscopy, and Transmission Electron Microscope (TEM). The thickness of TiO₂ layer and polymer electrolyte films were measured by using Scanning Electron Microscope (SEM) and Alpha-step 1Q. The surfaces of TiO₂ film, dyes adsorbed TiO₂ film, and interface adsorption of TiOPcs on TiO₂ films was investigated by SEM. Measurement of the I_V characteristics of DSSC devices was carried out using a Solar Simulator (300 W simulator, models 81150) under simulated solar light with ARC Lamp power supply (AM 1.5, 100 mW/cm²). The power conversion efficiency (η) of a DSSC device is given by Formula 1.

η=Pₒᵤₜ/Pᵢₙ=(J_{sc}*V_{oc})*FF/Pᵢₙ [Formula 1]

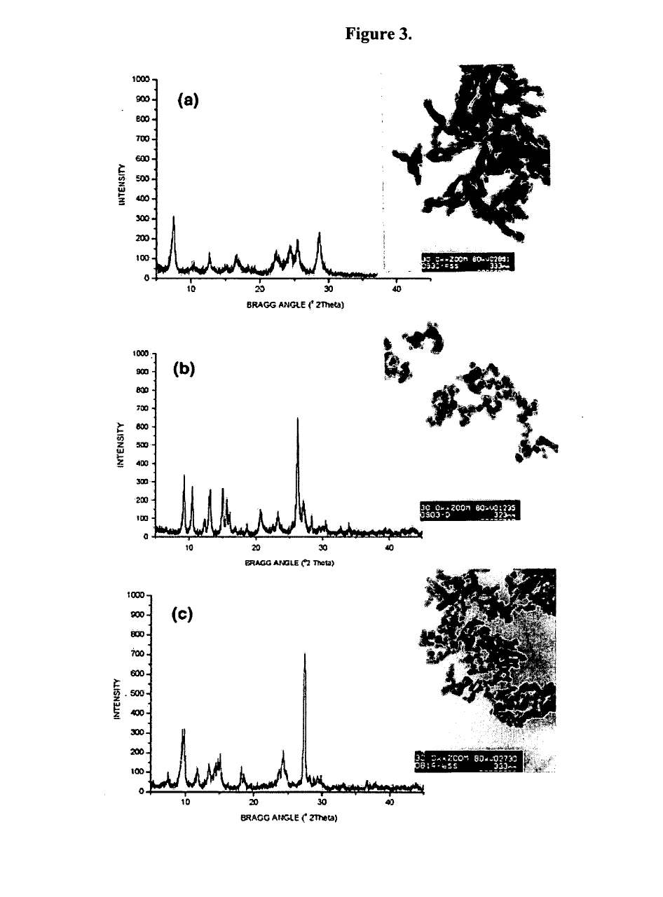

with FF=Pₘₐₓ/(J_{sc}*V_{oc})=(Jₘₐₓ*Vₘₐₓ)/(J_{sc}*V_{oc}) where Pₒᵤₜ is the output electrical power of the device under illumination, Pᵢₙ represented the intensity of the incident light (e.g., in W/m² of mW/cm²). V_{oc} is the open circuit voltage, J_{sc} is the short circuit current density, and fill factor (FF) is calculated from the values of V_{oc}, J_{sc}, and the maximum power point, Pₘₐₓ. FIG. 2 shows the FT-IR absorption spectra of TiOPcs in the wavenumber range 650-850 cm⁻¹. The FT-IR spectra of the PcT2000R, PcT3000R, and PcT1100S showed characteristic absorption peaks at 727-730 cm⁻¹ due to the γ C—H group, 749-753 cm⁻¹ due to δ-C₆H₆group, and 778-780 cm⁻¹ due to C—N group, respectively. In general, frequencies depend on the orientation of the planar phthalocyanine molecules, and the bands of longer wavenumber of thermodynamically stable polymorphs (beta-form) appear more intense than those of unstable (alpha, gamma-form) polymorphs. It has been able to be the beta-form in the most stable polymorphs and the bands became sharp due to well-stacked molecular interactions. In FIG. 2, we have confirmed that the beta-form (b) is the most stable polymorph, and the bands are sharp due to well-stacked molecular interactions. FIG. 3 shows XRD patterns of three TiOPcs as their crystal structures. And photographs of three TiOPcs polymorphs were taken by TEM. In the TEM images, the particle shapes are different from each other. The XRD patterns of TiOPcs have the strong peak; alpha-form: 2 Theta=7.58°, beta-form: 26.58°, and gamma-form: 27.58. The differences of XRD patterns seen among them were caused by the differences in their particle conditions. We have successfully confirmed the crystal structures of TiOPcs by TEM image and XRD pattern.

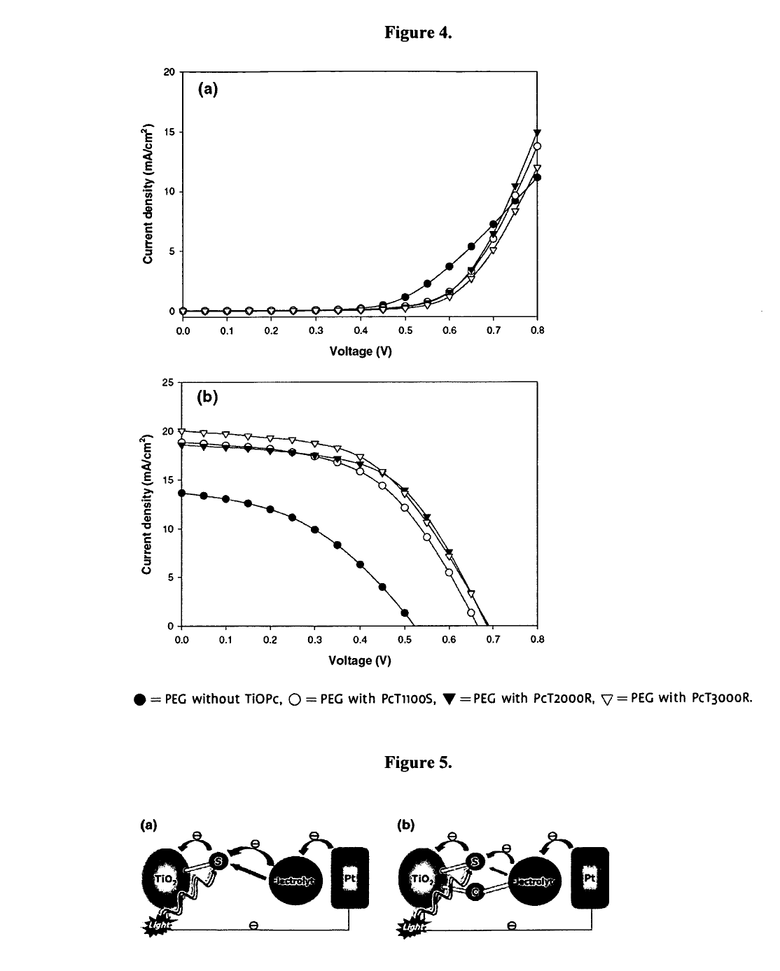

We have made of DSSC devices using the polymer electrolyte with the TiOPcs. The thicknesses of the cells were measured about 10 μm of nanocrystalline porous TiO₂ film and 3 μm of polymer electrolyte film by SEM and Alpha-step IQ, respectively. The photocurrent-voltage characteristics of the DSSC devices having three TiOPcs as a co-adsorbent using PEG as polymer matrix were shown in FIG. 4, and their characteristics were summarized in Table 1.

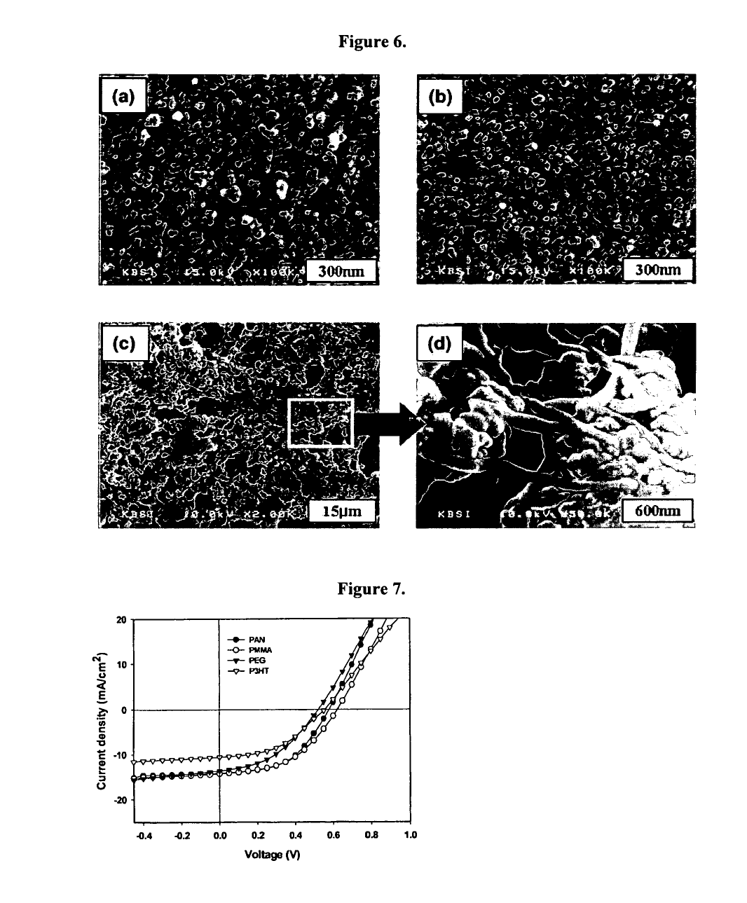

When TiOPcs were introduced into the PEG electrolyte, the power conversion efficiencies on DSSC devices were shown remarkably higher compared to those without TiOPc. This result was caused by the adsorption of TiOPc as a co-adsorbent on the interface between nanocrystalline porous TiO₂ films and polymer electrolyte, which may improve the electron transfer from the polymer matrix toward dyes-adsorbed nanoporous TiO₂ surface (FIG. 5). The polymer electrolyte contains 12, TBAI, 1-ethyl-3-methyl imidazolium iodide (EMImI) as an ionic liquid, EC/PC (EC:PC=4:1 v/v), polymer matrix such as polyethyleneglycol (PEG), and TiOPc as a co-adsorbent. FIG. 6 shows the SEM surface images of the nanocrystalline porous TiO₂ film, the dyes-adsorbed TiO₂ film, and polymer electrolyte film using PEG with PcT3000R. The bright part in the images (a) and (b) in FIG. 6 is titania, while dark part dispersed around titania is the impregnated dyes.

The Photovoltaic characteristics of the DSSC devices having
various TiOPcs using PEG electrolyte under AM 1.5 illumination

| | V_{oc} (V) | J_{sc} (mA/cm²) | FF | Eff. (%) |
|---|---|---|---|---|
| PEG | 0.52 | 13.66 | 0.42 | 2.97 |
| PEG with PcT1100S | 0.66 | 18.83 | 0.52 | 6.47 |
| PEG with PcT2000R | 0.68 | 18.58 | 0.55 | 7.05 |
| PEG with PcT3000R | 0.69 | 20.02 | 0.52 | 7.13 |

The above result shows influences of crystal structures of TiOPcs on DSSC device characteristics. Especially, among DSSC devices having three different TiOPcs, the device with a PcT3000R showed the highest value at 20.02 mA/cm² of Jsc and 7.13% of power conversion efficiency. From the results, it was found out that Jsc and conversion efficiency can be increased as the increase of conductivity polymer electrolyte by the addition PcT3000R, which has stable and well-stacked structure, on DSSC device.

### Comparative Example 1

DSSC devices using polymer electrolyte without the TiOPc have been prepared, in order to compare to those having polymer electrolyte with the TiOPc. From the results represented in Table 2 and FIG. 7, the photovoltaic parameters (Voc and FF) of DSSC device based on PAN, PMMA, and P3HT (irregular) matrix showed higher values than those of device based on PEG under same conditions. The Voc were 0.57, 0.62, and 0.55 V using PAN, PMMA, and P3HT (irregular) matrix, respectively. The fill factor were 0.53, 0.48, and 0.45 under 100 mA/cm² of light density at air mass 0.5, respectively. In general, the power conversion efficiency of DSSC is mainly dependent on the ionic conductivity of the polymer matrix. It was also demonstrated that, the ionic conductivity of polymer electrolytes can be increased as the state and additives in electrolyte. Since typically the ionic conductivities of PAN, PEG, PMMA are higher than PEG, the power conversion efficiency of DSSC devices based on other polymers matrix showed higher values than those of device based on PEG when Pc was not introduced into the electrolyte.

TABLE 2
The photovoltaic characteristics of the DSSC devices having
various polymers as a polymer matrix without TiOPc(PcT300R)
under AM 1.5 illumination.

| | V_{oc} (V) | J_{sc} (mA/cm²) | FF | Eff. (%) |
|---|---|---|---|---|
| PAN | 0.57 | 14.31 | 0.53 | 4.31 |
| PMMA | 0.62 | 14.29 | 0.48 | 4.22 |
| PEG | 0.52 | 13.66 | 0.42 | 2.97 |
| P3HT(irregular) | 0.55 | 10.62 | 0.45 | 2.63 |

### Example 2

We fabricated DSSC devices using PAN, PMMA, PEG, or P3HT(irregular) electrolytes as a polymer matrix with TiOPc as a coadsorbent, respectively. I_V curves under illumination are shown in FIG. 8 and the photovoltaic performances of DSSC devices are listed in Table 3. Current_voltage characteristics showed a significant improvement in the photovoltaic performance upon the addition of TiOPc into PEG matrix electrolyte, which has the highest value of 7.13% on power conversion efficiency. The power conversion efficiency increased over two times in comparison with that without TiOPc. The main reason for this results seemed to be caused by the delocalization of electrons among titanyl groups of TiOPc, ether groups of PEG and the surface of TiO₂ layer. The proposed mechanisms of the electrons delocalization in the contact interface can be described as shown in FIG. 6. When the TiOPc as a coadsorbent is introduced, it is adsorbed on adds the interface adsorption between TiO₂ surface and PEG matrix electrolyte. It can attribute to make PEG matrix close to dye molecules oxidized by light. This conjugated structure can improve the electron transfer from polymer matrix toward to dyes adsorbed nanoporous TiO₂ layer. Consequently, availability of electron transfer on the interface was increased due to the interface adsorption that caused the decreasing of electron transfer distance between TiO₂ layer and polymer electrolyte.

Moreover, when TiOPc was included in the PAN polymer electrolyte, the power conversion efficiency decreased from 4.31% to 4.08% in comparison with those without TiOPc. The Jsc also decreased from 41.31 mA/cm² to 13.12 mA/cm², on the other hand, the Voc increased from 0.57 V to 0.63V. These results can be attributed to the immiscibility of TiOPc with PAN, and the difficulty of the conjugation structure formation between the CN group of PAN and the titanyl group of TiOPc. However, since Voc was defined as a difference between Fermi level of TiO₂ layer and the redox potential of the electrolyte, as the introduction of TiOPc into the electrolyte, Voc on DSSC device can be increased.

TABLE 3
The photovoltaic characteristics of the DSSC devices having
TiOPc(PcT300R) as a coadsorbent using PEG electrolyte
under AM 1.5 illumination.

| | V_{oc} (V) | J_{sc} (mA/cm²) | FF | Eff. (%) |
|---|---|---|---|---|
| PAN | 0.63 | 13.12 | 0.49 | 4.08 |
| PMMA | 0.66 | 12.69 | 0.48 | 4.07 |
| PEG | 0.69 | 20.02 | 0.52 | 7.13 |
| P3HT(irregular) | 0.56 | 12.80 | 0.50 | 3.62 |

### Example 3

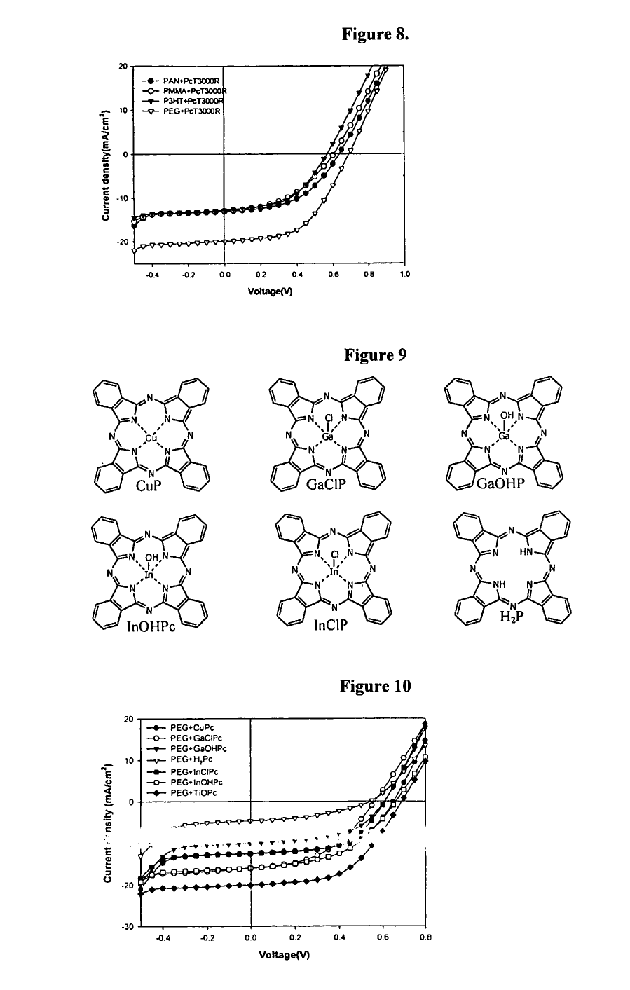

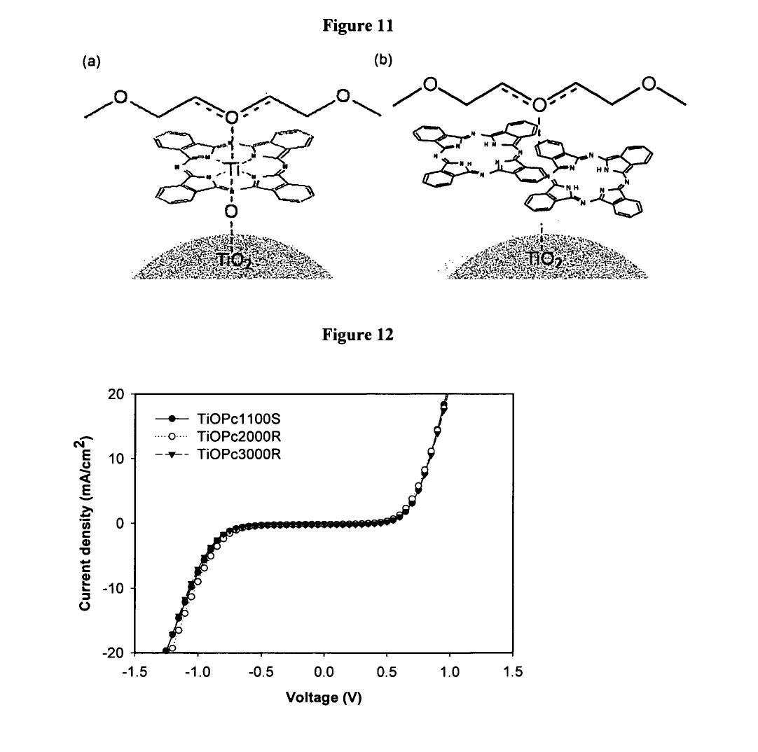

DSSC devices using various phthalocyanines with PEG polymer electrolyte has been made. FIG. 9 shows chemical structures of various phthalocyanines used. The photocurrent_voltage characteristics of the DSSC devices having various phthalocyanines as additive using PEG as polymer matrix were shown in FIG. 10, and their characteristics were summarized in Table 4. This result shows the influence of metal of phthalocyanines. A device having polymer electrolyte using a TiOPc (PcT3000R) as a coadsorbent was showed the highest conversion efficiency. In the same experimental conditions, the lowest value was found for the metal_free phthalocyanine. The result of DSSC without phthalocyanine was rather higher than that with metal_free phthalocyanine. The main reason for these results seemed to be caused by the delocalization of electrons among titanyl functional group of phthalocyanine, PEG and TiO₂ layer (FIG. 11). The photocurrent of DSSC device was obtained the highest value by the addition of TiOPc and the lowest value by metal free phthalocyanine.

TABLE 4
The photovoltaic characteristics of the DSSC devices having
phthalocyanines as a coadsorbent using PEG electrolyte
under AM 1.5 illumination.

| | V_{oc} (V) | J_{sc} (mA/cm²) | FF | Eff. (%) |
|---|---|---|---|---|
| CuPc | 0.65 | 12.34 | 0.56 | 4.51 |
| GaClPc | 0.56 | 15.97 | 0.45 | 4.05 |
| GaOHPc | 0.61 | 10.07 | 0.53 | 3.21 |
| H2Pc | 0.54 | 4.62 | 0.39 | 0.98 |
| InClPc | 0.61 | 12.55 | 0.55 | 4.24 |
| InOHPc | 0.66 | 15.93 | 0.48 | 5.04 |
| TiOPC(PcT3000R) | 0.69 | 20.02 | 0.52 | 7.13 |

### Example 4

The DSSCs were prepared and characterized in the same manner to Example 1 except that the phthalocyanine compounds were used as a photosensitizer but as a co-adsorbent of electrolyte. The obtained results is shown in FIG. 13 and Table 5.

TABLE 5
The photovoltaic characteristics of the DSSC devices with
phthalocyanines as a dye sensitizer under AM 1.5 illumination.

| | V_{oc} (V) | J_{sc} (mA/cm²) | FF | Eff. (%) |
|---|---|---|---|---|
| TiOPc1100S | 0.36 | 0.19 | 0.47 | 0.03 |
| TiOPc2000R | 0.37 | 0.21 | 0.47 | 0.04 |
| TiOPc3000R | 0.43 | 0.19 | 0.53 | 0.04 |

### [Working Effect]

Various phthalocyanine compounds have been prepared and characterized by FT-IR, TEM and XRD in order to identify their crystal structures, and DSSCs have been prepared from phthalocyanine compounds having different crystal structures. Power conversion efficiency of DSSC comprising phthalocyaine compound is at most 7.13%, which is significantly higher than those having no phthalocyanine compound.

1. An electrolyte comprising:
at least one phthalocyanine compound of Formula I:
X-MPc-(R)ₙ (I)
wherein,
Pc is a phthalocyanine moiety,
M is a metal selected from the group consisting of copper, iron, nickel, cobalt, manganese, aluminum, palladium, tin, indium, lead, titanium, rubidium, vanadium, gallium, terbium, cerium, lanthanum and zinc;
X is none, halogen, —OH or ═O; and
R is independently selected from hydrogen, alkyl, cyclic alkyl, arylalkyl, hydroxyalkyl, amino, alkylamino, alkoxy, alkylthio, aryl, aryloxy, arylthio, halogen and hydroxy groups;
n is an integer from 1 to 16.

2. The electrolyte according to claim 1, wherein M is selected from the group consisting of titanium, gallium, indium and copper.

3. The electrolyte according to claim 2, wherein the phthalocyanine compound is oxytitanium phthalocyanine.

4. The electrolyte according to claim 1, wherein the phthalocyanine compound has a crystal structure selected from gamma, alpha and beta forms.

5. The electrolyte according to claim 4, wherein the phthalocyanine compound has the crystal structure of beta form.

6. The electrolyte according to claim 1, further comprising a polymer matrix.

7. The electrolyte according to claim 6, wherein the polymer matrix is selected from the group consisting of polyethylene glycol (PEG), polypropylene glycol (PPG), polyacrylonitriles (PAN), polyacrylates, polymethacrylates (PMMA) and polythiophenes (PT).

8. The electrolyte according to claim 7, wherein the polymer matrix is polyethylene glycol.

9. A dye-sensitized solar cell device comprising:
a) a negative electrode
b) a nanocrystalline metal oxide comprising a dye sensitizer;
c) an electrolyte according to claim 1; and
d) a counter electrode.

10. The dye-sensitized solar cell device according to claim 9, wherein the dye sensitizer comprises a ruthenium-bipyridine complex.

11. The dye-sensitized solar cell device according to claim 9, wherein the nanocrystalline metal oxide comprises a nanocrystalline TiO₂.

12. The dye-sensitized solar cell device according to claim 9, wherein the negative electrode includes a fluorine-doped tin oxide (FTO) glass and the counter electrode includes FTO glass with thermally deposited Pt.

13. The dye-sensitized solar cell device according to claim 9, wherein the dye sensitizer is adsorbed and covalently bound on the nanocrystalline metal oxide.

14. A dye comprising:
at least one phthalocyanine compound of Formula I:
X-MPc-(R)ₙ (I)
wherein,
Pc is a phthalocyanine moiety,
M is a metal selected from the group consisting of copper, iron, nickel, cobalt, manganese, aluminum, palladium, tin, indium, lead, titanium, rubidium, vanadium, gallium, terbium, cerium, lanthanum and zinc;
X is none, halogen, —OH or ═O; and
R is independently selected from hydrogen, alkyl, cyclic alkyl, arylalkyl, hydroxyalkyl, amino, alkylamino, alkoxy, alkylthio, aryl, aryloxy, arylthio, halogen and hydroxy groups;
n is an integer from 1 to 16.

15. The dye according to claim 14, wherein M is selected from the group consisting of titanium, gallium, indium and copper.

16. The dye according to claim 15, wherein the phthalocyanine compound is oxytitanium phthalocyanine.

17. A solar cell comprising a dye according to claim 14.

18. The solar cell according to claim 17, further comprising: a negative electrode, a nanocrystalline metal oxide, an electrolyte, and a counter electrode, wherein the nanocrystalline metal oxide comprises the dye as a dye sensitizer.

19. The solar cell according to claim 17, having a structure of electron donor/electron acceptor, wherein the electron donor comprises the dye.

20. A method for manufacturing solar cells which comprises incorporating therein at least one phthalocyanine compound of Formula I
X-MPc-(R)ₙ (I)
wherein,
Pc is a phthalocyanine moiety,
M is a metal selected from the group consisting of copper, iron, nickel, cobalt, manganese, aluminum, palladium, tin, indium, lead, titanium, rubidium, vanadium, gallium, terbium, cerium, lanthanum and zinc;
X is none, halogen, —OH or ═O; and
R is independently selected from hydrogen, alkyl, cyclic alkyl, arylalkyl, hydroxyalkyl, amino, alkylamino, alkoxy, alkylthio, aryl, aryloxy, arylthio, halogen and hydroxy groups;
n is an integer from 1 to 16.

21. The method according to claim 20 wherein the phthalocyanine compound functions as a dye.

22. The method according to claim 20 wherein the phthalocyanine compound functions as an electrolyte component of the solar cell.

23. The method according to claim 22 wherein the phthalocyanine compound functions as a coadsorbent.
